(19) United States
(12) Patent Application Publication
(10) Pub. No.: US 2011/0049514 A1
(43) Pub. Date: Mar. 3, 2011

(54) TCP TYPE SEMICONDUCTOR DEVICE

(75) Inventors: Suguru SASAKI, Kanagawa (JP); Kouji Murakami, Kanagawa (JP)

(73) Assignee: Renesas Electronics Corporation, Kanagawa (JP)

(21) Appl. No.: 12/873,854

(22) Filed: Sep. 1, 2010

(30) Foreign Application Priority Data
Sep. 2, 2009 (JP) 2009-202987

(51) Int. Cl. H01L 23/498

(52) U.S. Cl. 257/48; 257/E23.06

(57) ABSTRACT

A TCP type semiconductor device includes a base film; a semiconductor chip mounted on the base film; and a plurality of leads formed on the base film and electrically connected with the semiconductor chip. Each of the plurality of leads has an external terminal portion exposed externally. The external terminal portion of the each lead includes: a first portion having a first thickness; and a second portion having a second thickness which is thinner than the first thickness. The first portion and the second portion are arranged to oppose to each other between adjacent two of the plurality of leads.

### INCORPORATION BY REFERENCE

This patent application claims a priority on convention based on Japanese Patent Application No. 2009-202987 filed on Sep. 2, 2009. This disclosure thereof is incorporated herein by reference.

### TECHNICAL FIELD

The present invention relates to a semiconductor device and a test method thereof. In particular, the present invention relates a TCP (Tape Carrier Package) type semiconductor device and a test method thereof.

### BACKGROUND ART

A probe card is known which is used for a test of a semiconductor device. The probe card includes a number of probes in contact with test terminals of a test subject. Therefore, the test is conducted by bring a tip of each of the probes into contact with the corresponding test terminal, supplying a test signal from a tester through the probe card to the test subject and obtaining an outputted signal from the test subject. At this time, in order to prevent a short-circuit failure, it is required to bring the probes into contact with the corresponding test terminals accurately.

On the other hand, in recent years, a pitch between the test terminals becomes narrower due to miniaturization of the semiconductor device and an increase in the number of the terminals. Thus, it is required for the probe card to correspond to narrowing of the pitch between the test terminals. For example, it is contemplated to reduce a pitch between the tips of adjacent probes of the probe card, along with narrowing of the pitch between the test terminals. However, since it is necessary to ensure insulating properties between the adjacent probes, there is a limit to reduce the pitch between the tips of the probes. Therefore, it has been proposed to distribute tip positions of the probes in a plurality of rows. Accordingly, it becomes possible to ensure the insulating property between the probes as well as reduce a substantial pitch between the tips of the probes. Thus, it is possible to correspond to narrowing of the pitch between the test terminals. The probe cards with such probe patterns are disclosed in Patent Literatures 1, 2 and 3, for example.

A TCP (Tape Carrier Package) type semiconductor device is also known. For the TCP type semiconductor device, a semiconductor chip is mounted on a base film such as a TAB (Tape Automated Bonding) tape. The TCP type semiconductor device also includes a film which is generally referred to as a COP (Chip On Film).

FIG. 1 is a plan view schematically illustrating a TCP type semiconductor device disclosed in Patent Literature 4. In FIG. 1, a semiconductor chip 120 is mounted on a base film (carrier tape) 110. A plurality of leads 130 and a plurality of contact pads 140 are also formed on the base film 110. Each of the plurality of leads 130 connects electrically a corresponding one of the plurality of contact pads 140 to a semiconductor chip 120.

More specifically, as shown in FIG. 1, a solder resist SR is formed so as to partially cover each of the leads 130. The solder resist SR is a resin applied on the leads 130, and functions to electrically insulate the leads 130 as well as to reduce chemical stress such as corrosion and, physical stress applied to the leads 130 by external force. The leads 130 formed in a region where the solder resist SR is not formed functions terminals electrically connectable to an outside, and such a region becomes a terminal region. The semiconductor chip 120 is mounted on a central terminal region where the solder resist SR is not formed, and a resin sealing is performed after mounting. On the other hand, an outer terminal region where the solder resist SR is not formed is an external terminal region and electrically connected to the contact pads 140.

The contact pads 140 are test terminals used in a test of the semiconductor device and are located in a predetermined region (pad layout region RP) on the base film 110. In other words, the probes of the probe card are in contact with the contact pads 140 in the pad layout region RP in the test of the semiconductor device. Therefore, a test signal is supplied through the contact pads 140 and the leads 130 to the semiconductor chip 120, and an output signal is obtained from the semiconductor chip 120. It should be noted that the probe card used herein also has a probe pattern in which the tip positions of the probes are distributed into a plurality of rows. Corresponding to such a probe pattern, the contact pads 140 is distributedly located into a plurality of rows as shown in FIG. 1.

In FIG. 1, a width direction and an extension direction of the base film 110 are along an x direction and a y direction, respectively. The structure shown in FIG. 1 is repeatedly formed along the y direction. After completion of the test, when the semiconductor chips 120 are cut one by one, the base film 110 and the plurality of the leads 130 are cut along a cut line CL shown by a dashed line in FIG. 1. At this time, the contact pads 140 within the pad layout region RP remains on the base film 110.

### CITATION LIST

[Patent Literature 1]; JP-A-Heisei 8-94668
[Patent Literature 2]: JP-A-Heisei 8-222299
[Patent Literature 3]: JU-A-Heisei 4-5643
[Patent Literature 4]: JP 2004-356339A

### SUMMARY OF THE INVENTION

In recent years, the number of terminals in the semiconductor chip is increased and the number of test signals supplied to the semiconductor chip and the number of signals outputted from the semiconductor chip during a test are also increased. This means an increase in the number of contact pads 140 in the TCP type semiconductor device shown in FIG. 1. The increase in the number of contact pads 140 introduces an increase of a pad layout region PR, i.e. increases of a width and a length of the base film 110. As a result, a manufacturing cost of the TCP type semiconductor device increases. Thus, the technique is desired that can reduce the manufacturing cost of the TCP type semiconductor device.

In an aspect of the present invention, a TCP type semiconductor device includes: a base film; a semiconductor chip mounted on the base film; and a plurality of leads formed on the base film and electrically connected with the semiconductor chip. Each of the plurality of leads has an external terminal portion exposed externally. The external terminal portion of the each lead includes: a first portion having a first thickness; and a second portion having a second thickness which is thinner than the first thickness. The first portion and the second portion are arranged to oppose to each other between adjacent two of the plurality of leads.

In another aspect of the present invention, a TCP type semiconductor device includes: a base film having a plurality of device regions, each of which is surrounded by a cut line, wherein the base film is cut along the cut line; and a plurality of semiconductor devices, each of which is arranged inside of a corresponding one of the plurality of device regions. Each of the plurality of semiconductor devices includes: a semiconductor chip arranged on the base film inside of the corresponding one of the plurality of device regions; and a plurality of leads formed on the base film and electrically connected with the semiconductor chip. Each of the plurality of leads has an external terminal portion exposed externally. The external terminal portion of the each lead includes: a first portion having a first thickness; and a second portion having a second thickness which is thinner than the first thickness. The first portion and the second portion are arranged to oppose to each other between adjacent two of the plurality of leads.

According to the present invention, the manufacturing cost of a TCP type semiconductor device can be reduced.

### BRIEF DESCRIPTION OF THE DRAWINGS

The above and other objects, advantages and features of the present invention will be more apparent from the following description of certain embodiments taken in conjunction with the accompanying drawings, in which:

FIG. 1 is a plan view schematically illustrating a conventional TCP type semiconductor device;

FIG. 2 is a plan view schematically illustrating a TCP type semiconductor device according to an embodiment of the present invention;

FIG. 3 is a plan view illustrating one unit of the TCP type semiconductor device according to the present embodiment;

FIG. 4 is a perspective view illustrating a structure of an external terminal portion according to the present embodiment;

FIG. 5 is a plan view of the configuration of the external terminal portion shown in FIG. 4;

FIG. 6 is a cross sectional view of the semiconductor device taken along a line A-A′ in FIG. 5;

FIG. 7 is a perspective view illustrating connections between the external terminal portions and probes according to the present embodiment;

FIG. 8 is a side view illustrating connections between the external terminal portions and the probes according to the present embodiment;

FIG. 9A illustrates a contact margin in a comparison example;

FIG. 9B illustrates a contact margin in the present embodiment;

FIG. 10 is a cross sectional view illustrating connection between the external terminal portion and a substrate side electrode;

FIG. 11 is a plan view illustrating a first modification of the external terminal portion according to the present embodiment;

FIG. 12 is a plan view illustrating a second modification of the external terminal portion according to the present embodiment;

FIG. 13 a plan view illustrating a third modification of the external terminal portion according to the present embodiment; and

FIG. 14 is a perspective view illustrating a fourth modification of the external terminal portion according to the present embodiment.

### DESCRIPTION OF EMBODIMENTS

Hereinafter, a TCP type semiconductor device according to the present invention will be described in detail with reference to the attached drawings.

### 1. Configuration

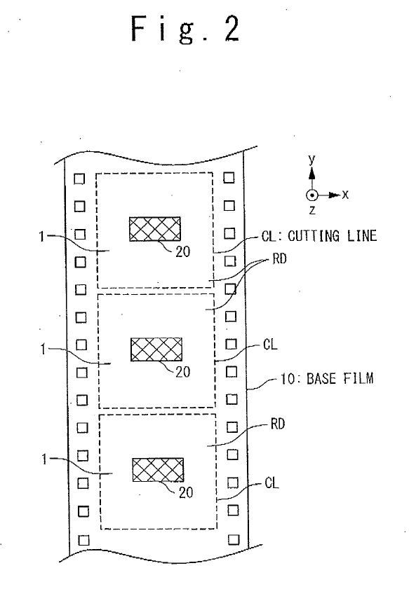

FIG. 2 schematically illustrates a configuration of a TCP type semiconductor device according to the present embodiment. A base film (carrier tape) 10 such as a TAB tape is used in the TCP type semiconductor device. As shown in FIG. 2, a width direction and an extension direction of the base film 10 are along an x direction and a y direction, respectively. The x direction and the y direction are along the directions orthogonal to each other.

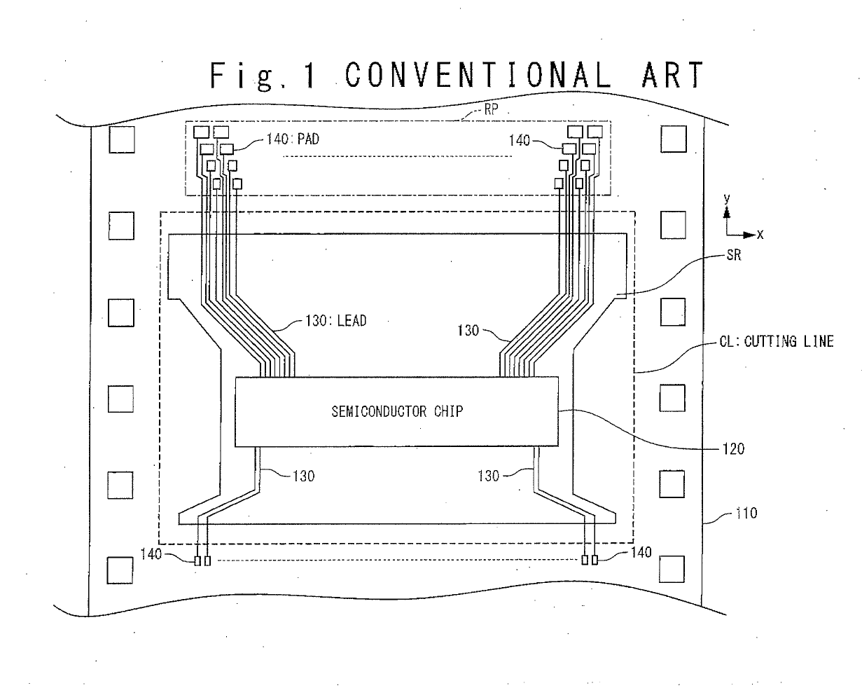

A plurality of semiconductor chips 20 are mounted on the base film 10. More specifically, the base film 10 has a plurality of device regions RD located sequentially along the y direction. Each of the device regions RDs is a region surrounded by a cut line CL on the base film 10. The plurality of the semiconductor chips 20 are located inside of the plurality of device regions RDs, respectively. One semiconductor device 1 corresponds entirely to the inside of one device region RD. That is to say, semiconductor devices 1 are repeatedly located on the base film 10 along the y direction. When the semiconductor devices are separated one by one, the base film 10 is cut along the cut line CL. It should be noted that in the present embodiment, a pad layout region PR as shown in FIG. 1 is not provided on the base film 10. As shown in FIG. 2, only the device region RD appears repeatedly.

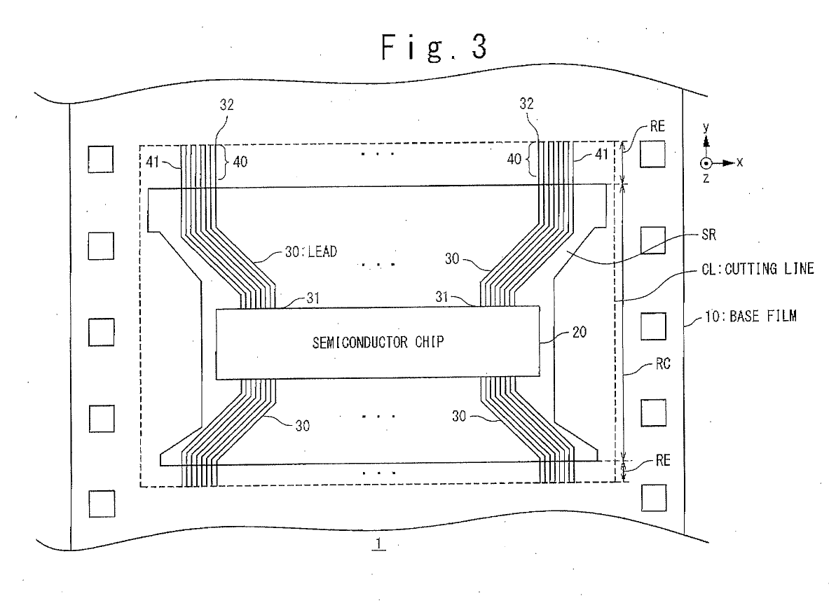

FIG. 3 illustrates one unit of the TCP type semiconductor device. As shown in FIG. 3, one semiconductor device 1 includes the semiconductor chip 20 mounted on the base film 10 and a plurality of leads 30 formed on the base film 10. The plurality of leads 30 are electrically connected to the semiconductor chip 20. More specifically, each of the leads 30 has a first end 31 and a second end 32 on an opposing side of the first end 31. Among two ends, the first end 31 is directly connected to the semiconductor chip 20 and the second end 32 is open.

In addition, a solder resist SR is formed so as to partially cover the leads 30. The solder resist SR is resin applied on the leads 30, and functions to electrically insulate the leads 30 as well as to reduce chemical stress such as corrosion and physical stress applied to the leads 30 by external force. The leads 30 in a region where the solder resist SR is not formed become terminals electrically connectable to the outside. The semiconductor chip 20 is mounted on a region in the vicinity of a central portion where the solder resist SR is not formed and a resin sealing is performed after mounting. The region covered with the solder resist SR or the semiconductor chip 20 in this way is referred to as a “covered region RC” hereinafter. The leads 30 in the covered region RC are basically covered with the solder resist SR or resin which is used for sealing after mounting the semiconductor chip 20, and the leads 30 in the covered region RC are not exposed.

On the other hand, in a region outside of the covered region RC, the leads 30 are exposed externally. The exposed portions of the leads 30 are external terminal portions (external connecting terminals) 40 used for connecting with other devices. For example, when the semiconductor chip 20 is an IC for driving a liquid crystal display panel, the external terminal portions 40 are connected to electrodes of the liquid crystal display panel. Accordingly, the liquid crystal display panel and the semiconductor chip 20 for driving the liquid crystal display panel are electrically connected to each other. It should be noted that the connecting procedure is generally referred to as OLB (Outer Lead Bonding).

A region where the external terminal portion 40 of each of the leads 30 is formed is hereinafter referred to as an “external terminal region (OLB region) RE”. As shown in FIG. 3, in the external terminal region RE, the external terminal portion 40 of each of the leads 30 extends in the y direction and the external terminal portions 40 are parallel to each other. Moreover, the tip portion of each of the external terminal portions 40 is the second end 32 mentioned above. It should be noted that of two opposing sides of the external terminal region RE, the side on the semiconductor chip 20 side corresponds to one side of the covered region RC, and the other side corresponds to one side of the cut line CL. That is, the external terminal region RE does not protrude outside of the cut line CL.

It should be noted that it is preferable that all the leads 30 have a same length in the external terminal region RE as shown in FIG. 3. In other words, it is preferable that the length of the external terminal portion 40 is the same over all the leads 30. Each of the external terminal portions 40 extends to a position of a same distance from the cut line CL and the positions of the second ends 32 (tip portion) are aligned along the x direction. The leads 30 with all of the tips thereof aligned in this way are preferred in facility of manufacture of the semiconductor device.

In the present embodiment, the pad layout region RP as shown in FIG. 1 is not provided on the base film 10. That is, the contact pad 140 dedicated for a test as shown in FIG. 1 is not provided, and the pad layout region RP is removed from the base film 10. As shown in FIG. 3, the second end 32 of each of the leads 30 is not connected to the contact pad dedicated for the test and forms a termination of the lead 30. All the leads 30 are formed inside the cut line CL without protruding outside the cut line CL.

According to the present embodiment, in the test of the semiconductor device 1, a contact pad dedicated for contact with the probe is not used. Instead of the contact pad, a portion of the external terminal portion 40 within the external terminal region RE is used for contact with the probe. This portion used for contact with the probe is hereinafter referred to as “a test pad portion”. That is to say, the external terminal portion 40 of each of the leads 30 has the test pad portion which is not only used for connect with the other device, but also is in contact with a probe during the test of the semiconductor device 1.

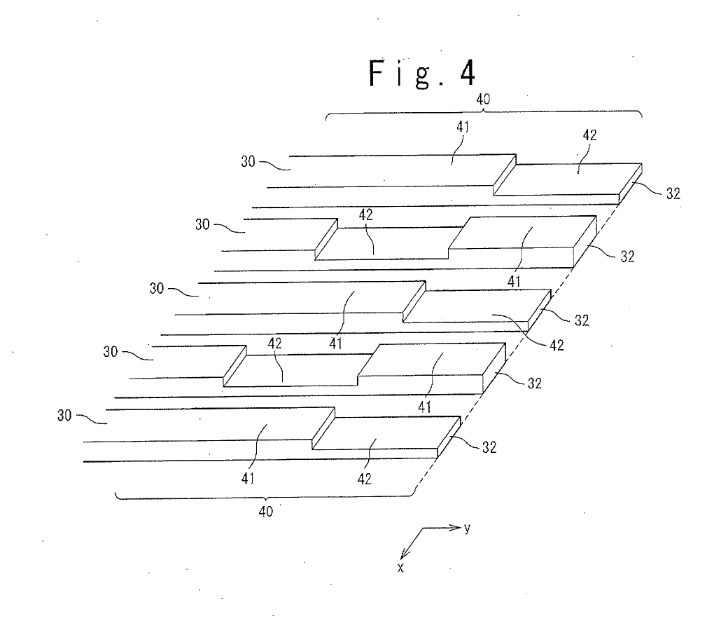

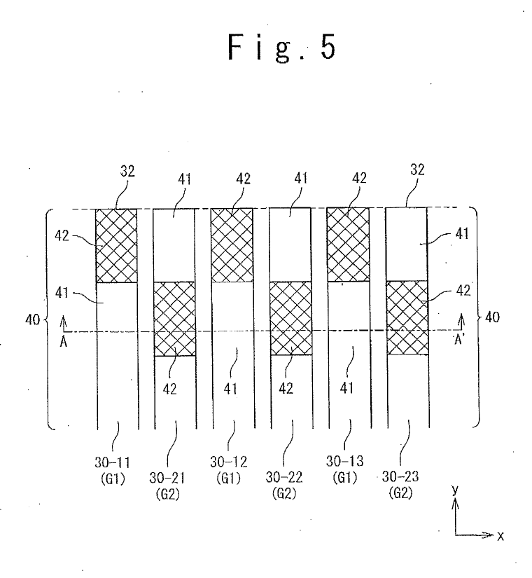

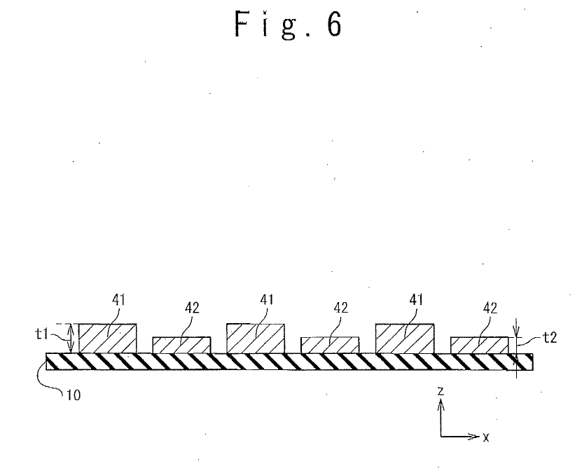

FIG. 4 is a perspective view illustrating a configuration example of the external terminal portion 40 according to the present embodiment. FIG. 5 is a plan view of the configuration shown in FIG. 4. FIG. 6 is a cross sectional view of the semiconductor device taken along the line A-A′ in FIG. 5. An x direction, a y direction and a z direction in FIGS. 4 to 6 are orthogonal to each other. The x direction and the y direction are parallel to the surface of the base film 10, and the z direction is a direction perpendicular to the base film 10. An extension direction of the external terminal portion 40 of each of the leads 30 is the y direction, the width direction thereof is the x direction and the thickness direction thereof is the z direction. The external terminal portions 40 of the plurality of leads 30 are formed substantially in parallel along the y direction and their widths are substantially same.

As shown in FIGS. 4 and 6, the external terminal portion 40 of each of the leads 30 includes a first portion 41 which is relatively thick, and a second portion 42 which is relatively thin. The thickness of the first portion 41 (height in the z direction) is a first thickness t1 and the thickness of the second portion 42 is a second thickness t2 thinner than the first thickness t1 (<t1). For example, the first thickness t1 is 8 μm and the second thickness t2 is 4 μm. In this way, the first portion 41 is thicker than the second portion 42 and the second portion 42 is thinner than the first portion 41. In other words, when seen from the base film 10, the first portion 41 is higher than the second portion 42 and the second portion 42 is lower than the first portion 41. In the external terminal portion 40 of each of the leads 30, the first portion 41 and second portion 42 are adjacent to each other, resulting in a step formed at a boundary between the first portion 41 and the second portion 42.

In addition, between the adjacent leads 30, the first portion 41 and the second portion 42 are positioned to oppose to each other. For example, in FIG. 5, a lead 30-11 is adjacent to a lead 30-21, and the first portion 41 of the lead 30-11 is opposed to the second portion 42 of the lead 30-21 while the first portion 41 of the lead 30-21 is opposed to the second portion 42 of the lead 30-11. The same is applied to combinations of other adjacent leads 30. As a result, the first portion 41 of the certain lead 30 must be located laterally to the second portion 42 of the adjacent lead 30. That is to say, the first portion 41 which is high is surrounded by the second portions 42 which are low. In the present embodiment, this high first portion 41 surrounded by the low second portions 42 is used as the above-mentioned “test pad portion”. In this case, as described later in detail, a contact margin is increased and a pitch between the leads 30 can be reduced.

In the external terminal region RE, it is preferable that the first portions 41 and the second portions 42 are arranged regularly or periodically. For example, in FIG. 5, the second portions 42 are located in one of two locations in a staggered manner. More specifically, the plurality of leads 30 is divided into two groups G1 and G2. The first group G1 includes leads 30-1i and the second group G2 includes leads 30-2i (i=1, 2, 3, . . . ). For the leads 30-1i of the first group G1, the first portions 41 are aligned along the direction and the second portions 42 are also aligned along the x direction. Moreover, for the leads 30-2i of the second group G2, the first portions 41 are aligned along the x direction and the second portions 42 are also aligned along the x direction. Therefore, the leads 30-1i of the first group G1 and the leads 30-2i of the second group G2 are arranged alternately. When the first portions 41 and the second portions 42 are arranged regularly in this way, it is facilitated to bring each probe into contact with the corresponding test pad portion (41) accurately one by one.

It should be noted that, in the example shown in FIGS. 4 to 6, the thick first portion 41 occupies most of the region of the external terminal portion 40 and the thin second portion 42 is formed only in the small region thereof. In this meaning, the first portion 41 can be referred to as a normal portion and the second portion 42 can be referred to as a recess portion. The recess portion 42 can be formed by wet-etching a predetermined region of the external terminal portion 40 (normal portion) or the similar processing. As shown in FIGS. 4 and 5, the recess portions 42 are positioned differently between the adjacent leads 30 in the y direction. That is, the positions of the recess portions 42 are shifted in the y direction between the adjacent leads 30. As a result, the positions of the test pad portions 41 are shifted in the y direction. It should be noted that it is preferable that a length of the recess portion 42 along the y direction is uniform over the plurality of the leads 30.

### 2. Test and Mounting 2-1. Test

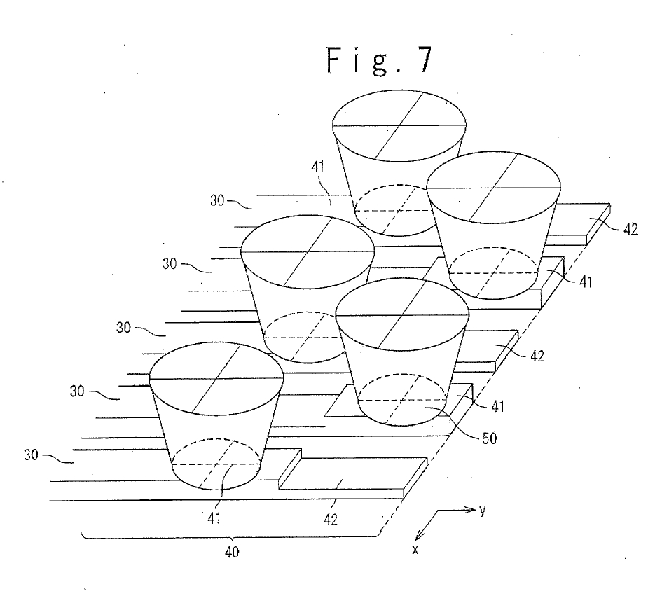

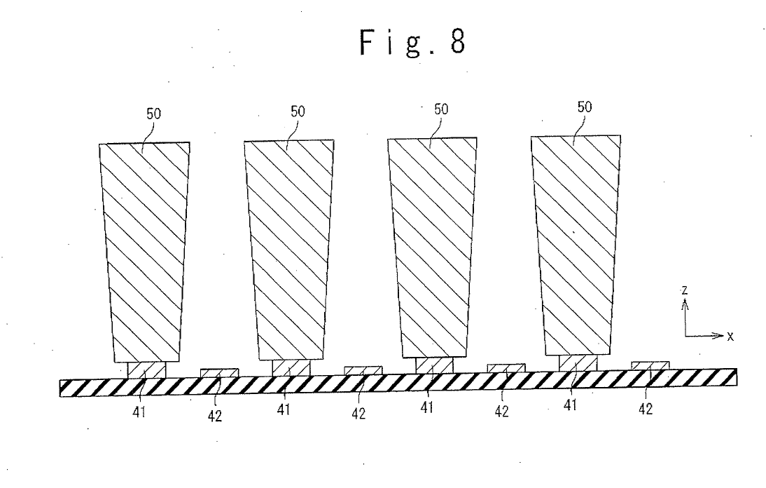

According to the present embodiment, in the test of the semiconductor device 1, a contact pad dedicated for contact with a probe is not used. Instead of the contact pad, a portion of the external terminal portions 40 within the external terminal region RE (first portion 41) is used as a test pad portion for contact with the probe. FIGS. 7 and 8 are a perspective view and a side view, respectively, which illustrate the connections between the external terminal portions 40 and the probes 50 during the test. As shown in FIGS. 7 and 8, the probes 50 is in contact with the high first portions 41 surrounded by the low second portions 42. That is to say, the high first portions 41 surrounded by the low second portions 42 function as the “test pad portion”.

The contact pad 140 dedicated for the test as shown in FIG. 1 is not provided, and the pad layout region RE is removed from the base film 10. As a result, an area of the base film required for one semiconductor chip 20 can be reduced significantly relative to that shown in FIG. 1. Thus, it becomes possible to reduce the material cost and improve an arrangement efficiency of the semiconductor chips 20 on the base film 10. Accordingly, the manufacturing cost of the semiconductor device 1 can be reduced.

In addition, between the adjacent leads 30, the positions of the test pad portions 41 are shifted in the y direction. Thus, the probes 50 connected to the test pad portions 41 of the adjacent leads 30 are prevented from generating a short-circuit.

Moreover, surrounding the test pad portion 41 by the low second portions 42 means that spaces around the test pad portion 41 are ensured. Thus, even if the probe positions are shifted slightly, it is prevented that one probe 50 is in contact with both of the adjacent leads 30 simultaneously. In other words, a tolerance for the position shift of the probe 50 becomes larger and the contact margin is increased.

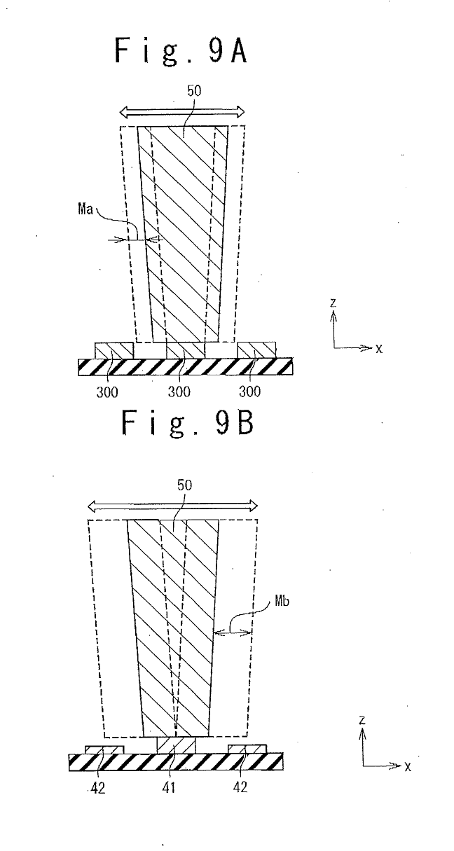

As a comparison example, as shown in FIG. 9A, the contact of the probe 50 with the leads 300 with a same height is assumed. When a tip diameter of the probe 50 is equal to or more than a width of the lead 300, a tolerance (contact margin Ma) for the position shift of the probes 50 falls principally in a range less than a spacing between the leads 300 (distance between opposing sides of the adjacent leads). When the positions of the probes 50 shift more than the spacing, the probe 50 is in contact with two adjacent leads 300 simultaneously to generate a short-circuit error. Accordingly, the contact margin Ma in the case of FIG. 9A is small. In order to increase the contact margin Ma, it is necessary to increase the pitch between the leads 300. However, it goes against the requirement for miniaturization of the semiconductor device.

FIG. 9B illustrates a case according to the present embodiment. In the present embodiment, the test pad portion 41 is sandwiched between the low second portions 42 and the spaces around the test pad portion 41 are ensured. Thus, a tolerance (contact margin Ma) for the position shift of the probe 50 increases apparently relative to that in FIG. 9A. That is, even if the position shift of the probe 50 is equal to or more than the spacing between the leads 30, the short-circuit error will not occur. This means that the pitch between the leads 30 can be reduced without the short-circuit error. As the pitch between the leads 30 is reduced, an area of the base film 10 required for arranging the leads 30 is reduced. This is preferable in terms of preventing an increase in the cost due to miniaturization of the semiconductor device and an increase in the number of terminals in recent years.

### 2-2. Cutting

When the TCP type semiconductor devices 1 are cut one by one, the base film 10 is cut along the cut line CL (see FIGS. 2 and 3). At this time, according to the present embodiment, it is possible to reduce short-circuit failure due to metal debris.

The case shown in FIG. 1 is assumed as a comparison example. In this comparison example, the semiconductor chip 120 is connected though the leads 130 to the contact pads 140 for the test. Thus, when the semiconductor devices 1 are cut one by one, it is necessary to cut the leads 130 along the cut line CL. The metal debris generated in this process may cause the short-circuit failure later. On the other hand, according to the present embodiment, the contact pads 140 for the test are not provided. As shown in FIG. 3, the leads 30 are formed only inside of the device region RD surrounded by the cut line CL. Thus, the leads 30 are not cut when the semiconductor devices 1 are cut one by one. As a result, the short-circuit failure due to the metal debris can be reduced. In addition, the efficiency can be obtained that, because it is not necessary for jig for punching the semiconductor device along the cut line CL to cut the leads 300 made of metal, the life of the jig is extended.

### 2-3. Mounting

The semiconductor chip 20 according to the present embodiment is an IC for driving a display panel such as a liquid crystal display panel and a plasma display panel. The semiconductor chip 20 is electrically connected through the leads 30 to electrodes of the display panel. More specifically, the display panel includes a plurality of pixels formed on a substrate in matrix and a plurality of electrodes (data lines) formed on the substrate to drive the pixels. The plurality of electrodes is electrically connected to each of the plurality of the leads 30 of the TCP type semiconductor device 1 (package) according the present embodiment. The electrodes connected to the leads 30 in this way are hereinafter referred to as “substrate side electrodes 70”.

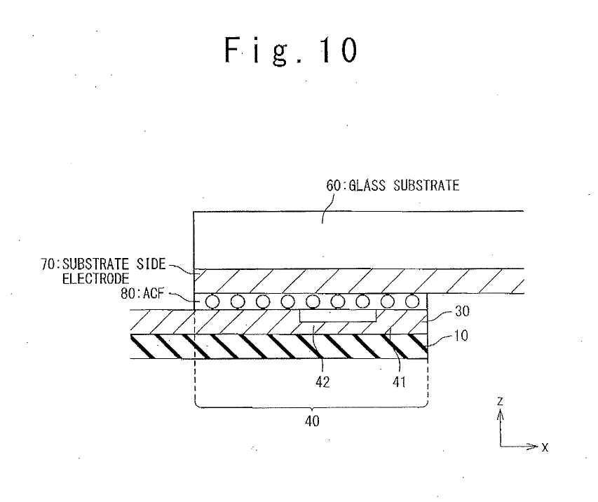

FIG. 10 is a cross sectional view illustrating connection between the external terminal portion 40 and the substrate side electrode 70. The substrate side electrode 70 is formed on a glass substrate 60 of the display panel. The substrate side electrode 70 is connected through an ACF (Anisotropic Conductive Film) 80 to the external terminal portion 40 of the TCP type semiconductor device 1. On an external terminal portion 40 side, the high first portion 41 is in contact with the ACF 80. In terms of a contact area, it is desirable that the low second portion 42 (recess portion) is as small as possible. In addition, it is preferable that the length of the second portion 42 (recess portion) along the y direction is uniform between the plurality of leads 30. In that case, a contact area of the external terminal portion 40 and the ACF 80 becomes uniform.

### 3. Modifications

### 3-1. First Modification

In the aforementioned example shown in FIG. 5, the tips (second ends 32) of the leads 30-i1 in the first group G1 are included in the thin second portions 42 and the tips (second ends 32) of the leads 30-i2 pertained in the second group G2 are included in the thick first portion 41. That is to say, tip thicknesses of the external terminal portions 41 connected to the substrate side electrode 70 are varied depending on the leads 30.

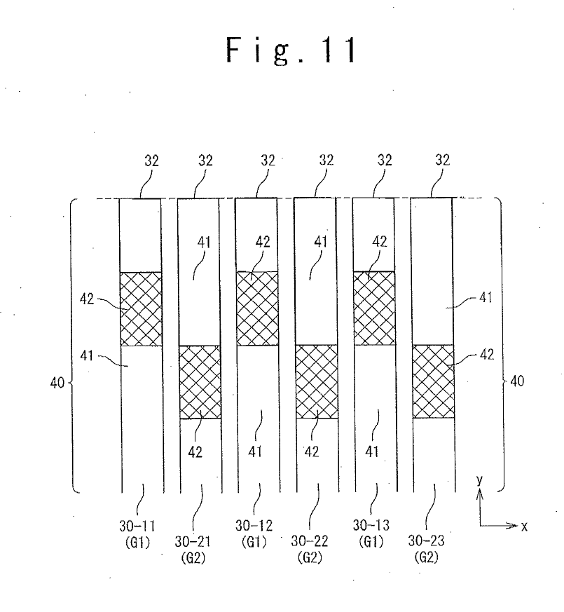

FIG. 11 is a plan view illustrating a first modification of the external terminal portion 40. In this modification, the tips (second ends 32) of all the leads 30 are included in the thick first portion 41. That is to say, the tip thicknesses of the external terminal portions 40 are uniform over all the leads 30. In this case, balance upon connecting the external terminal portion 40 to the substrate side electrode 30 is improved.

### 3-2. Second Modification

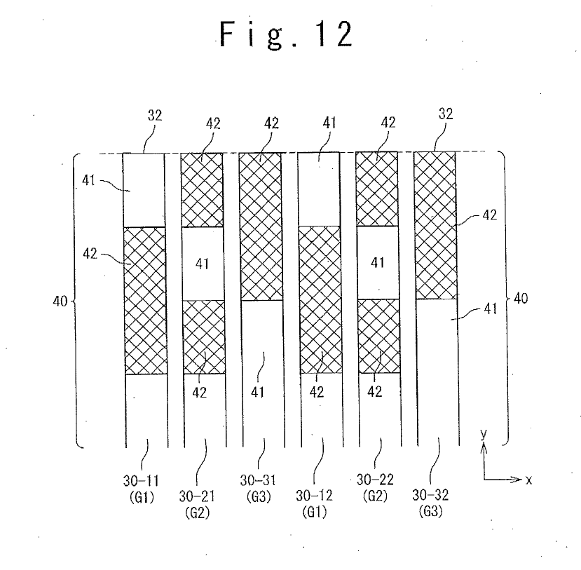

Although the test pad portions 41 are arranged to be distributed into two stages in the aforementioned example shown in FIG. 5, the test pad portions 41 may be distributed into three stages or more. For example, in FIG. 12, the test pad portions 41 are arranged to be distributed into three stages. In this case, the plurality of leads 30 are divided into three groups G1 to G3. The first group G1 includes the leads 30-1i, the second group G2 includes the leads 30-2i, and the third group G3 includes the leads 30-3i (i=1, 2, . . . ). Even in this case, the same effect as above can be obtained.

### 3-3. Third Modification

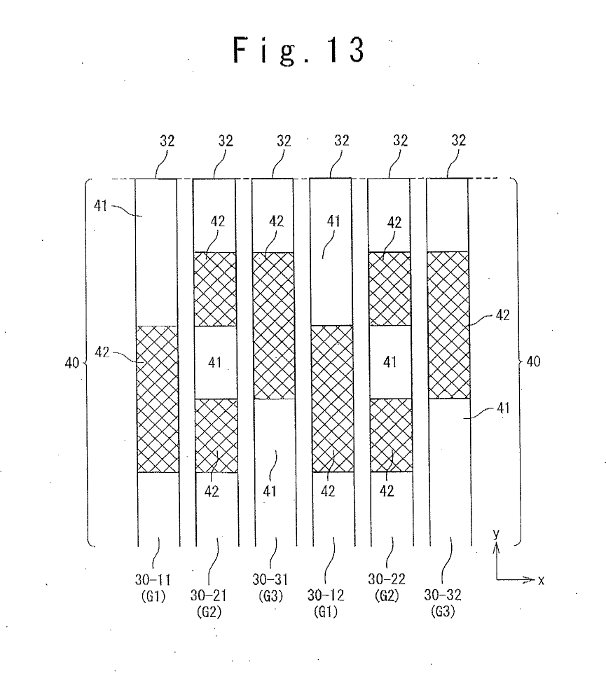

FIG. 13 is a plan view illustrating a third modification of the external terminal portion 40. The third modification is a combination of the first modification and the second modification.

### 3-4. Fourth Modification

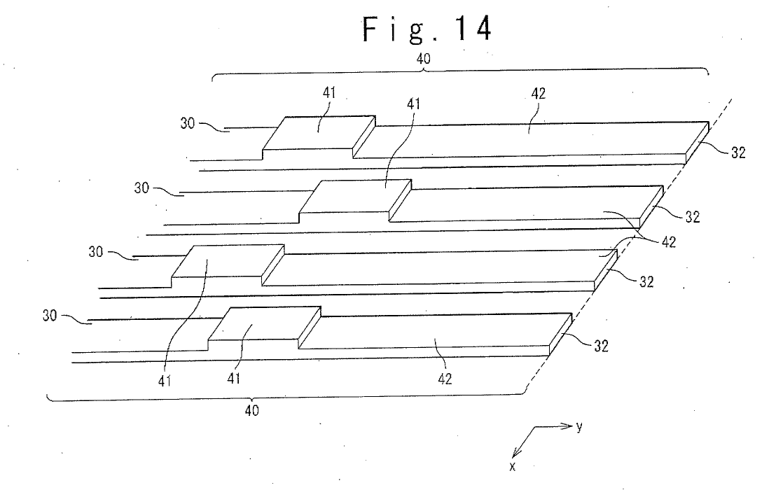

FIG. 14 is a perspective view illustrating a fourth modification of the external terminal portion 40. In this modification, the thin second portion 42 occupies most of the region of the external terminal portion 40 and the thick first portion 41 is formed only in a small region thereof. In this meaning, the second portion 42 can be referred to as a normal portion and the first portion 41 can be referred to as a bump portion. In this modification, this bump portion 41 is used as a test pad portion. Between the adjacent leads 30, the positions of the bump portions (test pad portions 41) are shifted in the y direction. It is preferable to use the second portion 42 for connection with the substrate side electrode 70. Even in this case, the same effect as above can be obtained.

Hereinbefore, the embodiment of the present invention has been described with reference to the attached drawings. However, it should be noted that the present invention is not limited to the aforementioned embodiments and can be changed accordingly by the skilled persons in the art without departing from the principle of the present invention.

What is claimed is:

1. A TCP type semiconductor device comprising:
a base film;
a semiconductor chip mounted on said base film; and
a plurality of leads formed on said base film and electrically connected with said semiconductor chip,
wherein each of said plurality of leads has an external terminal portion exposed externally,
wherein said external terminal portion of said each lead comprises:
a first portion having a first thickness; and
a second portion having a second thickness which is thinner than said first thickness, and
wherein said first portion and said second portion are arranged to oppose to each other between adjacent two of said plurality of leads.

2. The TCP type semiconductor device according to claim 1, wherein said external terminal portion of said each lead extends in a first direction, and a second direction is in parallel to a surface of said base film and orthogonal to the first direction,
wherein said plurality of leads is grouped into at least two groups, and
wherein in each of said at least two groups, said first portions are aligned along the second direction and said second portions are aligned along the second direction.

3. The TCP type semiconductor device according to claim 1, wherein said external terminal portion of said each lead extends into the first direction, and a length of said second portion in the first direction is same over said plurality of leads.

4. The TCP type semiconductor device according to claim 1, wherein a thickness of a tip of said external terminal portion is identical over said plurality of leads.

5. The TCP type semiconductor device according to claim 1, wherein said first portion is a test pad portion which is contact with a probe in a test.

6. A TCP type semiconductor device comprising:
a base film having a plurality of device regions, each of which is surrounded by a cut line, wherein said base film is cut along the cut line; and
a plurality of semiconductor devices, each of which is arranged inside of a corresponding one of said plurality of device regions,
wherein each of said plurality of semiconductor devices comprises:
a semiconductor chip arranged on said base film inside of the corresponding one of said plurality of device regions; and
a plurality of leads formed on said base film and electrically connected with said semiconductor chip,
wherein each of said plurality of leads has an external terminal portion exposed externally,
wherein said external terminal portion of said each lead comprises:
a first portion having a first thickness; and
a second portion having a second thickness which is thinner than said first thickness, and
wherein said first portion and said second portion are arranged to oppose to each other between adjacent two of said plurality of leads.

7. The TCP type semiconductor device according to claim 6, wherein said external terminal portion of said each lead extends in a first direction, and a second direction is in parallel to a surface of said base film and orthogonal to the first direction,
wherein said plurality of leads is grouped into at least two groups, and
wherein in each of said at least two groups, said first portions are aligned along the second direction and said second portions are aligned along the second direction.

8. The TCP type semiconductor device according to claim 6, wherein said external terminal portion of said each lead extends into the first direction, and a length of said second portion in the first direction is same over said plurality of leads.

9. The TCP type semiconductor device according to claim 6, wherein a thickness of a tip of said external terminal portion is identical over said plurality of leads.

10. The TCP type semiconductor device according to claim 6, wherein said first portion is a test pad portion which is contact with a probe in a test.
